(19) United States
(12) Patent Application Publication
(10) Pub. No.: US 2022/0372612 A1
(43) Pub. Date: Nov. 24, 2022

(54) CONSISTENT KNOWN VOLUME LIQUID METAL OR METAL ALLOY TRANSFER FROM ATMOSPHERIC TO VACUUM CHAMBER

(71) Applicant: Applied Materials, Inc., Santa Clara, CA (US)

(72) Inventors: PRASANNAKALLESHWARA BUDDAPPA RAMACHANDRAPPA, Santa Clara, CA (US); Sambhu Nath Kundu, Fremont, CA (US); Vicente M. Lim, Newark, CA (US); Visweswaren Sivaramakrishnan, Cupertino, CA (US); Subramanya P. Herle, Mountain View, CA (US)

(21) Appl. No.: 17/663,549

(22) Filed: May 16, 2022

Related U.S. Application Data
(60) Provisional application No. 63/191,643, filed on May 21, 2021.

(51) Int. Cl. C23C 14/24; C23C 14/14; C23C 14/54

(52) U.S. Cl. CPC C23C 14/246; C23C 14/14; C23C 14/54

(57) ABSTRACT

Methods and systems for the delivery of molten metals and metal alloys at a fixed volume are provided. The system includes an evaporation system having a fluid inlet port and a fluid delivery system. The fluid delivery system includes an ampoule operable to hold a source material. The ampoule includes a fluid outlet port and a gas inlet port. The fluid delivery system further includes a fluid delivery line operable to deliver the source material to the evaporation system. The fluid delivery line includes a first end fluidly coupled with the fluid outlet port and a second end fluidly coupled to the fluid inlet port. The fluid delivery line further includes a first isolation valve disposed along the fluid delivery line and a second isolation valve disposed along the fluid delivery line which define a fixed volume of the fluid delivery line.

### CROSS-REFERENCE TO RELATED APPLICATIONS

This application claims benefit of U.S. Provisional Patent Application No. 63/191,643, filed May 21, 2021, which is herein incorporated by reference in its entirety.

### BACKGROUND

### Field

The present disclosure generally relates to methods and systems for the transfer of molten metals and metal alloys. More particularly, the present disclosure generally relates to methods and systems for the delivery of molten metals and metal alloys at a fixed volume.

### Description of the Related Art

Processing of flexible substrates, such as plastic films or foils, is in high demand in the packaging industry, semiconductor industries and other industries. Processing may include coating of a flexible substrate with a chosen material, such as a metal or a metal alloy. The economical production of these coatings is frequently limited by the thickness uniformity necessary for the product, the reactivity of the coating material, the cost of the coating materials, and the deposition rate of the coating materials. The most demanding applications generally involve deposition, which occurs in a vacuum chamber for precise control of the coating thickness and the optimum optical properties. The high capital cost of vacuum coating equipment necessitates a high throughput of coated area for large-scale commercial applications.

A process that can utilize a large vacuum chamber has tremendous economic advantages. One technique used is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible. It is difficult to deliver a fixed volume of the source material, such as a molten metal or a molten metal alloy, to the crucible without the source material splashing within the chamber. Thus, overfilling and underfilling of the source material may occur because the volume of the source material entering the crucible is unknown.

Thus, there is a need in the art for methods and systems for the delivery of molten metals and metal alloys at a fixed volume.

### SUMMARY

Implementations described herein generally relate to methods and systems for the transfer of molten metals and metal alloys. More particularly, the present disclosure generally relates to methods and systems for the delivery of molten metals and metal alloys at a fixed volume. In one implementation, a fluid delivery system is provided. The fluid delivery system includes an ampoule operable to hold a source material. The ampoule includes a fluid outlet port and a gas inlet port. The fluid delivery system further includes a fluid delivery line operable to deliver the source material to an evaporation system. The fluid delivery line includes a first end fluidly coupled with the fluid outlet port and a second end operable to be in fluid communication with the evaporation system. The fluid delivery line further includes a first isolation valve disposed along the fluid delivery line and a second isolation valve disposed along the fluid delivery line. The fluid delivery line further includes a calibration cylinder disposed along the fluid delivery line between the first isolation valve and the second isolation valve.

In another implementation, a deposition system is provided. The system includes an evaporation system having a fluid inlet port. The system further includes a fluid delivery system. The fluid delivery system includes an ampoule operable to hold a source material. The ampoule includes a fluid outlet port and a gas inlet port. The fluid delivery system further includes a fluid delivery line operable to deliver the source material to the evaporation system. The fluid delivery line includes a first end fluidly coupled with the fluid outlet port and a second end fluidly coupled to the fluid inlet port. The fluid delivery line further includes a first isolation valve disposed along the fluid delivery line and a second isolation valve disposed along the fluid delivery line. The fluid delivery line further includes a calibration cylinder disposed along the fluid delivery line between the first isolation valve and the second isolation valve.

In yet another implementation, a method of fluid delivery is provided. The method includes opening a first isolation valve disposed along a fluid delivery line and closing a second isolation valve disposed along the fluid delivery line. The fluid delivery line includes a first end fluidly coupled with an ampoule holding a source material and a second end in fluid communication with a crucible. The fluid delivery line further includes a first isolation valve disposed along the fluid delivery line and a second isolation valve disposed along the fluid delivery line. The first isolation valve and the second isolation valve define a fixed volume of the fluid delivery line. The fluid delivery line further includes a calibration cylinder disposed along the fluid delivery line between the first isolation valve and the second isolation valve. The method further includes delivering the source material from the ampoule to fill the fixed volume of the fluid delivery line. The source material passes through the calibration cylinder. The method further includes closing the first isolation valve when the fixed volume of the fluid delivery line is filled. The method further includes opening the second isolation valve such that the fixed volume of the source material flows through the fluid delivery line to the crucible.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a schematic side view of an evaporation system having an evaporation source according to one or more implementations of the present disclosure.

FIG. 2 illustrates a schematic view of a processing environment according to one or more implementations of the present disclosure.

FIG. 3 illustrates a process flow chart summarizing one implementation of a method for delivery of molten metals and metal alloys at a fixed volume according to one or more implementations of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Reference will now be made in detail to the various implementations of the present disclosure, one or more examples of which are illustrated in the figures. Within the following description of the drawings, the same reference numbers refer to the same components. Generally, only the differences with respect to individual implementations are described. Each example is provided by way of explanation of the present disclosure and is not meant as a limitation of the present disclosure. Further, features illustrated or described as part of one implementation can be used on or in conjunction with other implementations to yield yet a further implementation. It is intended that the description includes such modifications and variations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

According to some implementations, systems and methods for delivery of a source material to an evaporation apparatus for layer deposition on substrates, for example on flexible substrates, are provided. Thus, flexible substrates can be considered to include among other things films, foils, webs, strips of plastic material, metal or other materials. Typically, the terms “web,” “foil,” “strip,” “substrate” and the like are used synonymously. According to some implementations, which may be combined with other implementations described herein, components for evaporation processes and evaporation apparatuses according to implementations described herein can be provided for the above-described flexible substrates. However, components and apparatuses can also be provided in conjunction with non-flexible substrates such as glass substrates or the like, which are subject to the reactive deposition process from evaporation sources.

Vacuum web coating for anode pre-lithiation and solid metal anode protection involves thick (three to twenty micron) metallic (e.g., lithium) deposition on double-side-coated and calendered alloy-type graphite anodes and current collectors, for example, six micron or thicker copper foil, nickel foil, or metallized plastic web. One technique for deposition is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible.

Delivering a fixed volume of the source material to the crucible consistently is desirable. However, it can be difficult to deliver the fixed volume of the source material, such as a molten metal or a molten metal alloy, to the crucible as the volume of the source material being delivered is generally unknown. As a result, overfilling, underfilling, and splashing of the source material may occur as the source material is delivered to the crucible. Thus, it would be advantageous to have methods and systems for the delivery of molten metals and metal alloys at a fixed volume.

Implementations of the present disclosure provide for a system. The system includes an evaporation system having a fluid inlet port. The system further includes a fluid delivery system. The fluid delivery system includes an ampoule operable to hold a source material. The ampoule includes a fluid outlet port and a gas inlet port. The fluid delivery system further includes a fluid delivery line operable to deliver the source material to the evaporation system. The fluid delivery line includes a first end fluidly coupled with the fluid outlet port and a second end fluidly coupled to the fluid inlet port. The fluid delivery line further includes a first isolation valve disposed along the fluid delivery line and a second isolation valve disposed along the fluid delivery line. The fluid delivery line further includes a calibration cylinder disposed along the fluid delivery line between the first isolation valve and the second isolation valve.

Implementations of the present disclosure further provide for a method. The method includes opening a first isolation valve disposed along a fluid delivery line and closing a second isolation valve disposed along the fluid delivery line. The fluid delivery line includes a first end fluidly coupled with an ampoule holding a source material and a second end in fluid communication with a crucible. The fluid delivery line further includes a first isolation valve disposed along the fluid delivery line and a second isolation valve disposed along the fluid delivery line. The first isolation valve and the second isolation valve define a fixed volume of the fluid delivery line. The fluid delivery line further includes a calibration cylinder disposed along the fluid delivery line between the first isolation valve and the second isolation valve. The method further includes delivering the source material from the ampoule to fill the fixed volume of the fluid delivery line. The source material passes through the calibration cylinder. The method further includes closing the first isolation valve when the fixed volume of the fluid delivery line is filled. The method further includes opening the second isolation valve such that the fixed volume of the source material flows through the fluid delivery line to the crucible.

Implementations of the present disclosure include one or more of the following advantages. Isolation valves disposed along a fluid delivery line of the fluid delivery system allows for the reduction of overfilling and underfilling of the crucible with source material in the evaporation system by allowing for the delivery of a fixed volume of the source material. Additionally, the fluid delivery system reduces splashing of the source material. The fluid delivery system allows for an exact measurement of the source material delivered to the evaporation system, which reduces waste of the source material and reduces cost of ownership.

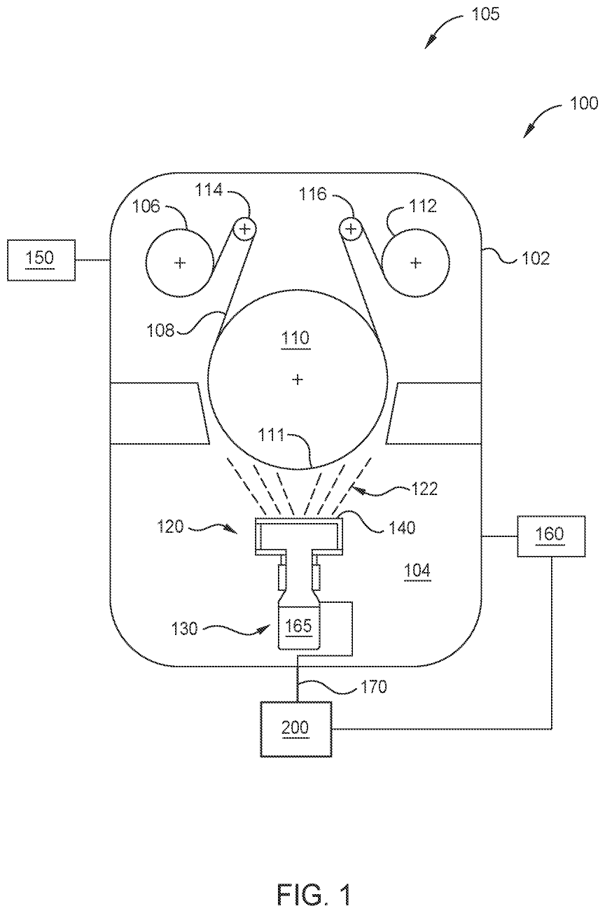

FIG. 1 illustrates a schematic side view of a deposition system 105 according to one or more implementations of the present disclosure. The deposition system 105 includes an evaporation system 100 and a fluid delivery system 200. The evaporation system 100 can be a SMARTWEB® system, manufactured by Applied Materials, and adapted for manufacturing metal containing film stacks according to the implementations described herein. In one example, the evaporation system 100 can be used for manufacturing lithium-containing anodes, and particularly for film stacks for lithium-containing anodes. The evaporation system 100 includes a chamber body 102 that defines a common processing environment 104 in which some or all of the processing actions for manufacturing lithium-containing anodes can be performed. The common processing environment 104 is operable as a vacuum environment. In another example, the common processing environment 104 is operable as an inert gas environment. In some examples, the common processing environment 104 can be maintained at a process pressure of 1×10⁻³ mbar or below, for example, 1×10⁻⁴ mbar or below.

The evaporation system 100 is constituted as a roll-to-roll system including an unwinding roll 106 for supplying a continuous flexible substrate 108, a coating drum 110 over which the continuous flexible substrate 108 is processed, and a winding roll 112 for collecting the continuous flexible substrate. The coating drum 110 includes a deposition surface 111 over which the continuous flexible substrate 108 travels while material is deposited onto the continuous flexible substrate 108. The evaporation system 100 can further include one or more auxiliary transfer rolls 114, 116 positioned between the unwinding roll 106, the coating drum 110, and the winding roll 112. According to one aspect, at least one of the one or more auxiliary transfer rolls 114, 116, the unwinding roll 106, the coating drum 110, and the winding roll 112, can be driven and rotated, by a motor. Although the unwinding roll 106, the coating drum 110, and the winding roll 112 are shown as positioned in the common processing environment 104, it should be understood that the unwinding roll 106 and the winding roll 112 can be positioned in separate chambers or modules, for example, at least one of the unwinding roll 106 can be positioned in an unwinding module, the coating drum 110 can be positioned in a processing module, and the winding roll 112 can be positioned in an unwinding module.

The unwinding roll 106, the coating drum 110, and the winding roll 112 can be individually temperature controlled. For example, the unwinding roll 106, the coating drum 110, and the winding roll 112 can be individually heated using an internal heat source positioned within each roll or an external heat source.

The evaporation system 100 further includes the evaporation source 120. The evaporation source 120 is positioned to perform one processing operation to the continuous flexible substrate 108 or web of material. In one example, as depicted in FIG. 1, the evaporation source 120 is radially disposed about the coating drum 110. In addition, arrangements other than radial are contemplated. In one implementation, which may be combined with other implementations described herein, the evaporation source is operable to hold a source material 165. The source material 165 to be deposited can be provided in a crucible 130. The material to be deposited can be evaporated, for example, by thermal evaporation techniques.

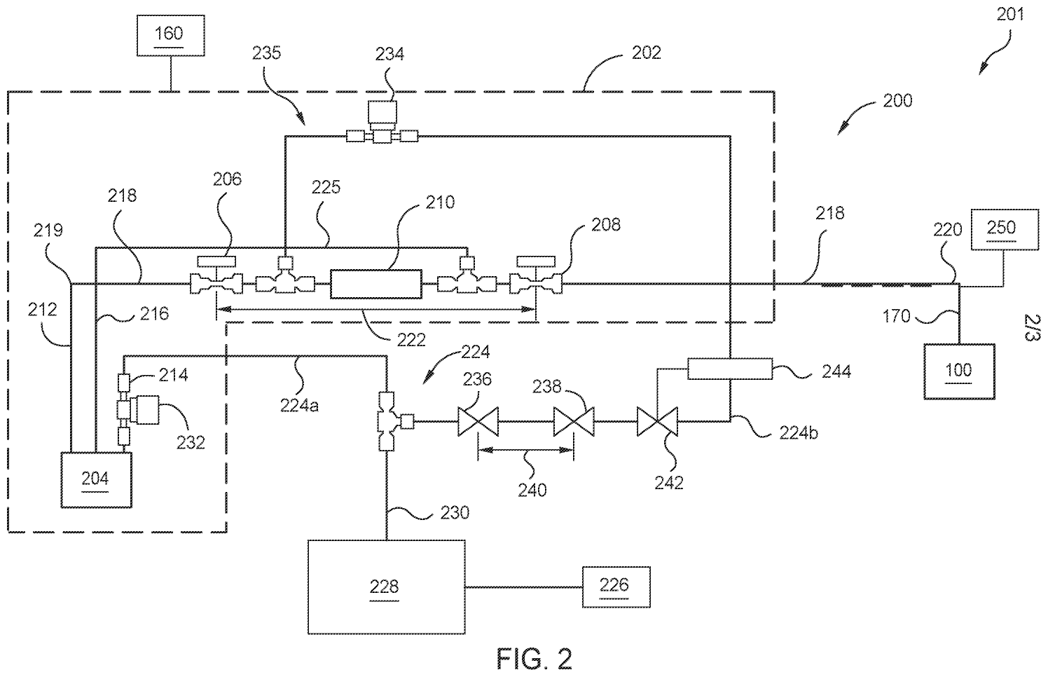

The crucible 130 is fluidly coupled with an evaporator body 140. The evaporator body 140 is operable to deliver evaporated material for deposition. The crucible 130 can be fluidly coupled with the evaporator body 140. The crucible 130 includes a monolithic restricted orifice vessel capable of holding a deposition material. The crucible 130 is operable for holding the source material 165 to be deposited. The evaporation system 100 includes a fluid inlet port 170. The fluid inlet port 170 is in fluid communication with the crucible 130. The source material 165 may be provided to the crucible 130 from the fluid delivery system 200 (as shown in FIG. 2) via the fluid inlet port 170.

In operation, the evaporation source 120 emits a plume of evaporated material 122, which is drawn to the continuous flexible substrate 108 where a film of deposited material is formed on the continuous flexible substrate 108.

In addition, although a single evaporation source, the evaporation source 120, is shown, it should be understood that the evaporation system 100 can further include one or more additional deposition sources. For example, the one or more deposition sources as described herein can include an electron beam source and additional sources, which can be selected from the group of CVD sources, PECVD sources, and various PVD sources. Exemplary PVD sources include sputtering sources, electron beam evaporation sources, and thermal evaporation sources.

In some implementations, which may be combined with other implementations described herein, the evaporation source 120 is positioned in a sub-chamber (not shown). The sub-chamber can isolate the evaporation source 120 from the common processing environment 104. The sub-chamber can include any suitable structure, configuration, arrangement, and/or components that enable the evaporation system 100 to deposit metal containing film stacks according to implementations of the present disclosure. For example, but not limited to, the sub-chambers may include suitable deposition systems including coating sources, power sources, individual pressure controls, deposition control systems, and temperature control. In some implementations, which may be combined with other implementations described herein, the sub-chamber is provided with individual gas supplies.

In some implementations, which may be combined with other implementations described herein, the evaporation system 100 is configured to process both sides of the continuous flexible substrate 108. For example, additional evaporation source similar to the evaporation source 120 can be positioned to process the opposing side of the continuous flexible substrate 108. Although the evaporation system 100 is configured to process the continuous flexible substrate 108, which is horizontally oriented, the evaporation system 100 can be configured to process substrates positioned in different orientations, for example, the continuous flexible substrate 108 can be vertically oriented. In some implementations, which may be combined with other implementations described herein, the continuous flexible substrate 108 is a flexible conductive substrate. In some implementations, which may be combined with other implementations described herein, the continuous flexible substrate 108 includes a conductive substrate with one or more layers formed thereon. In some implementations, which may be combined with other implementations described herein, the conductive substrate is a copper substrate.

The evaporation system 100 further includes a gas panel 150. The gas panel 150 uses one or more conduits (not shown) to deliver processing gases to the evaporation system 100. The gas panel 150 can include mass flow controllers and shut-off valves, to control gas pressure and flow rate for each individual gas supplied to the evaporation system 100.

The evaporation system 100 further includes a controller 160 operable to control various aspects of the evaporation system 100 and the fluid delivery system 200. The controller 160 facilitates the control and automation of the evaporation system 100 and the fluid delivery system 200 and can include a central processing unit (CPU), memory, and support circuits (or I/O). Software instructions and data can be coded and stored within the memory for instructing the CPU. The controller 160 can communicate with one or more of the components of the evaporation system 100 and the fluid delivery system 200 via, for example, a system bus. A program (or computer instructions) readable by the controller 160 determines which tasks are performable on a substrate. In some aspects, the program is software readable by the controller 160, which can include code for monitoring chamber conditions, controlling the evaporation source 120, and controlling the delivery of the source material 165 from the fluid delivery system 200. Although a single system controller, the controller 160 is shown, it should be appreciated that multiple system controllers can be used with the aspects described herein. The controller 160 may be one of any form of general-purpose computer processor that can be used in an industrial setting for controlling various chambers and sub-processors.

FIG. 2 illustrates a schematic view of a processing system 201 according to one or more implementations of the present disclosure. The processing system 201 includes a fluid delivery system 200 and an evaporation system 100. The fluid delivery system 200 is suitable for delivering a source material (e.g., the source material 165 shown in FIG. 1) to the evaporation system 100. The evaporation system 100 may be a system operable to conduct thermal evaporation of the source material. The fluid delivery system 200 is operable as an atmospheric pressure environment.

The fluid delivery system 200 includes a cabinet 202, shown in dotted lines. The cabinet 202 is operable to house an ampoule 204, a first isolation valve 206, a second isolation valve 208, and a calibration cylinder 210. In some implementations, which may be combined with other implementations described herein, the fluid delivery system 200 further includes a first check valve 232 and a second check valve 234. In some implementations, which may be combined with other implementations described herein, the ampoule 204 is intended to be used with the fluid delivery system 200, but is not a part of the fluid delivery system 200. The ampoule 204 includes a fluid outlet port 212 and a gas inlet port 214. In some implementations, which may be combined with other implementations described herein, the ampoule 204 includes a circulation inlet port 216.

The ampoule 204 is operable to hold the source material. The source material is a molten metal or metal alloy. Examples of the source material include, but are not limited to, alkali metals (e.g., lithium and sodium), magnesium, zinc, cadmium, aluminum, gallium, indium, thallium, selenium, tin, lead, antimony, bismuth, tellurium, alkali earth metals, silver, or combinations thereof. Further, the source material can also be an alloy of two or more metals. In one implementation, which may be combined with other implementations described herein, for reasons of chemical compatibility and mechanical strength, the ampoule 204 is made of a stainless steel, such as 316 stainless steel (316 SST). In one implementation, which may be combined with other implementations described herein, the material of the ampoule 204 is fairly chemically inert since different types of chemical precursors, such as highly reactive materials may be stored within the ampoule 204.

The fluid outlet port 212 of the ampoule 204 is in fluid communication with a fluid delivery line 218. In some implementations, which may be combined with other implementations described herein, the fluid delivery line 218 is partially housed in the cabinet 202. A first end 219 of the fluid delivery line 218 is fluidly coupled to the fluid outlet port 212. A second end 220 of the fluid delivery line 218 is fluidly coupled to the fluid inlet port 170 of the evaporation system 100. In operation, the source material is operable to travel through the fluid delivery line 218 from the ampoule 204 to the evaporation system 100. In one implementation, which can be combined with other implementations described herein, one or both of the fluid delivery line 218 and the fluid inlet port 170 include a heat source 250 coupled thereto. The heat source 250 is operable to provide heat to the source material in the fluid delivery line 218 and/or the fluid inlet port 170. For example, the heat source 250 will provide heat to line heaters or bullet heaters wrapped along the fluid delivery line 218 from the calibration cylinder 210 to the evaporation system 100. In one example, the heat source 250 maintains the source material at a temperature that will maintain the source material in a liquid state. For example, the source material is maintained at about 250° C. The heat source 250 prevents cold spots in the fluid delivery line 218 during delivery of the source material.

The fluid delivery line 218 includes a first isolation valve 206 and a second isolation valve 208. The second isolation valve 208 is disposed downstream of the first isolation valve 206. The first isolation valve 206 and the second isolation valve 208 define a fixed volume 222 of the fluid delivery line 218. The fixed volume 222 can be from about 1 mL to about 1000 mL (e.g., from about 200 mL to about 800 grams or from about 400 grams to about 600 grams).

The first isolation valve 206 can be opened to allow fluid communication between the fixed volume 222 and the ampoule 204. The second isolation valve 208 can be opened to allow fluid communication between the fixed volume 222 and the evaporation system 100. In operation, the second isolation valve 208 is closed and the first isolation valve 206 is open such that the fixed volume 222 may be filled with the source material. The first isolation valve 206 is closed when the fixed volume 222 is filled with the source material. The source material in the fixed volume 222 may then be delivered to the evaporation system 100 when the second isolation valve 208 is opened. The pressure differential between the cabinet 202 (operating in an atmospheric pressure environment) and the evaporation system 100 (operating in a vacuum environment) allows the source material to be delivered to the evaporation system 100.

The fluid delivery line 218 further includes the calibration cylinder 210 disposed between the first isolation valve 206 and the second isolation valve 208. In some implementations, which may be combined with other implementations described herein, the calibration cylinder 210 is included in the fixed volume 222. The calibration cylinder 210 is between about 1 mL to 100 mL. In operation, the calibration cylinder 210 is utilized to confirm that the fixed volume 222 is filled with the source material. Further, the calibration cylinder 210 confirms the exact volume of the source material in the fixed volume 222. Therefore, an exact volumetric measurement of the source material being delivered to the evaporation system 100 may be obtained, leading to a decrease in overfilling and underfilling the crucible of the evaporation system 100.

In some implementations, which may be combined with other implementations described herein, the fluid delivery system 200 further includes a gas delivery line 224 in fluid communication with a push gas source 226. The push gas source 226 is operable to hold a push gas. In some implementations, which may be combined with other implementations described herein, the gas delivery line 224 is partially housed in the cabinet 202. Examples of suitable push gases include inert gases such as helium, nitrogen, argon, or combinations thereof. In one implementation, which may be combined with other implementations described herein, the push gas is operable to provide a pressure to the source material such that the source material is delivered through the fluid delivery line 218. The push gas source 226 is in fluid communication with a gas platter 228. The gas platter 228 is coupled to a gas delivery outlet 230 fluidly coupled to the gas delivery line 224. The gas platter 228 may further include one or more conduits (not shown) to deliver processing gases to the fluid delivery system 200. The gas platter 228 can include mass flow controllers, pressure gauges, and shut-off valves, to control gas pressure and flow rate for each individual gas, such as the push gas, supplied to the fluid delivery system 200. For example, the gas platter 228 may facilitate the introduction of the push gas into the gas delivery outlet 230.

The gas delivery line 224 includes a first section 224a and a second section 224b. The first section 224a of the gas delivery line 224 connects the gas delivery outlet 230 and the gas inlet port 214 of the ampoule 204. The gas inlet port 214 includes the first check valve 232. The first check valve 232 facilitates the delivery of the push gas to the ampoule 204. The first check valve 232 can be open to allow the flow of the push gas behind the source material to push the source material through the fluid delivery line 218. The push gas is operable to purge the fluid delivery line 218 to ensure there are no reactions with the source material from external gases.

The second section 224b of the gas delivery line 224 connects the gas delivery outlet 230 and an overflow line 235. The overflow line 235 is fluidly coupled to the fluid delivery line 218. Additional source material that does not fit in the fixed volume 222 may flow into the overflow line 235. The second section 224b includes the second check valve 234. The second check valve 234 facilitates the delivery of the push gas to the overflow line 235. The second check valve 234 can be open to allow the flow of the push gas behind the source material to push the source material through the fluid delivery line 218 and out of the overflow line 235. Additionally, the second check valve 234 prevents the source material in the overflow line 235 from entering the gas delivery line 224. The push gas is operable to purge the fluid delivery line 218 to ensure there are no reactions with the source material from external gases.

In some implementations, which may be combined with other implementations described herein, the second section 224b of the gas delivery line 224 includes a first pneumatic valve 236 and a second pneumatic valve 238. The second pneumatic valve 238 is disposed downstream of the first pneumatic valve 236. The first pneumatic valve 236 and the second pneumatic valve 238 define a fixed gas volume 240 of the gas delivery line 224. The first pneumatic valve 236 can be opened to allow fluid communication between the fixed gas volume 240 and the gas platter 228. The second pneumatic valve 238 can be opened to allow fluid communication between the fixed gas volume 240 and the overflow line 235. In operation, the second pneumatic valve 238 is closed and the first pneumatic valve 236 is open such that the fixed gas volume 240 is filled with the push gas. The first pneumatic valve 236 is closed when the fixed gas volume 240 is filled with the push gas. The push gas in the fixed gas volume 240 may then be delivered to the overflow line 235 and the fluid delivery line 218. In some implementations, which may be combined with other implementations described herein, the second section 224b includes a metering valve 242 downstream of the second pneumatic valve 238. The metering valve 242 is in communication with a pressure gauge 244. The pressure gauge 244 is disposed downstream of the metering valve 242. The metering valve 242 is operable to reduce pressure applied to the push gas flowing to the fluid delivery line 218. The metering valve 242 may be adjusted based on pressure measurements provided from the pressure gauge 244. Thus, the metering valve 242 ensures that the source material will not splash when being delivered to the evaporation system 100 due to pressure. The metering valve 242 and the pressure gauge 224 allow for pressure control within the fluid delivery line 218 by monitoring and adjusting pressure of the push gas delivered to the fluid delivery line 218. In one example, the pressure in the fluid delivery line 218 is between about 10 mbar to about 500 mbar.

In some implementations, which may be combined with other implementations described herein, a circulation line 225 connects to the fluid delivery line 218 downstream of the calibration cylinder 210 and upstream of the second isolation valve 208. The circulation line 225 is fluidly coupled to the circulation inlet port 216 such that the circulation line is in fluid communication with the ampoule 204. In some implementations, which may be combined with other implementations described herein, when the second isolation valve 208 is closed and the first isolation valve 206 is open, the circulation line 225 allows the source material to circulate from the fluid delivery line 218 to the circulation line 225 and to the ampoule 204 via the circulation inlet port 216. Therefore, the circulation line 225 allows the source material to be circulated such that there is no trapped push gas in the fluid delivery line 218. Additionally, excess source material may be circulated back to the ampoule 204 to reduce waste of the source material.

The controller 160 may be provided and coupled to various components of the processing system 201 to control the operation thereof. The methods as described herein may be stored in a memory of the controller 160 as software routine that may be executed or invoked to control the operation of the fluid delivery system 200 and/or the evaporation system 100 in the manner described herein. In one implementation, which may be combined with other implementations described herein, the controller 160 is operable to control the first isolation valve 206, the second isolation valve 208, the first pneumatic valve 236, the second pneumatic valve 238, the metering valve 242, the first check valve 232, and the second check valve 234. In one implementation, which may be combined with other implementations described herein, the controller 160 is connected to the cabinet 202 and is operable to control the flow rate and volume of the source material and the push gas flowing into and out of the cabinet and to monitor the performance of the fluid delivery system 200.

In operation, a source material, for example, a molten metal such as lithium (Li) is stored in the ampoule 204. The source material flows into the fixed volume 222 of the fluid delivery line 218. The calibration cylinder 210 monitors the source material in the fixed volume 222 and confirms when the fixed volume 222 is filled with the source material. The second isolation valve 208 is opened and the source material is delivered to the evaporation system 100 via the fluid delivery line 218. The source material is delivered due to the differential pressure between the cabinet 202 and the evaporation system 100. In some implementations, a push gas is delivered to the fluid delivery line 218 via the gas delivery line 224. The push gas provides a pressure to the source material such that the source material is delivered through the fluid delivery line 218. The fixed volume 222 holding the source material allows for a known volume of source material to be repeatedly delivered to the evaporation system 100. Therefore, overfilling, underfilling, and splashing of the source material in a crucible 130 (shown in FIG. 1) of the evaporation system 100 is reduced.

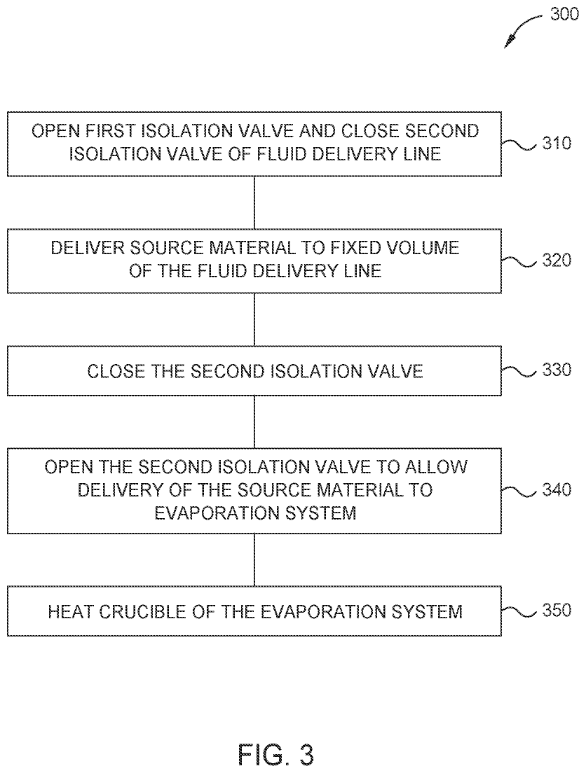

FIG. 3 illustrates a process flow chart 300 summarizing one implementation of a method for delivery of molten metals and metal alloys at a fixed volume according to one or more implementations of the present disclosure. In one implementation, which may be combined with other implementations described herein, the method is stored on a computer readable medium. In one implementation, which may be combined with other implementations described herein, the method is performed using the processing system 201. The method is described with reference to FIG. 1 and FIG. 2.

At operation 310, a first isolation valve 206 is opened and a second isolation valve 208 is closed. The first isolation valve 206 and the second isolation valve 208 are disposed along a fluid delivery line 218. The fluid delivery line 218 is at least partially housed in a cabinet 202 of a fluid delivery system 200. The fluid delivery line 218 connects an ampoule 204 and an evaporation system 100. The second isolation valve 208 is disposed downstream of the first isolation valve 206 along the fluid delivery line 218. The first isolation valve 206 and the second isolation valve 208 define a fixed volume 222 of the fluid delivery line 218.

At operation 320, a source material is delivered to the fixed volume 222. The source material is stored in the ampoule 204. The source material is delivered to the fixed volume 222 until the fixed volume 222 is filled with the source material. A calibration cylinder 210 disposed in the fixed volume 222 monitors the source material and confirms when the fixed volume 222 is filled. The calibration cylinder 210 also confirms the exact volume of the source material in the fixed volume 222. The source material is a molten metal or metal alloy. Examples of the source material include alkali metals (e.g., lithium and sodium), magnesium, zinc, cadmium, aluminum, gallium, indium, thallium, selenium, tin, lead, antimony, bismuth, tellurium, alkali earth metals, silver, or combinations thereof. In one example, the source material includes lithium, selenium, or sodium. Further, the source material can also be an alloy of two or more metals.

In some implementations, which may be combined with other implementations described herein, a push gas provides a pressure to the source material to deliver the source material to the fixed volume 222. Examples of suitable push gases include inert gases such as helium, nitrogen, argon, or combinations thereof. The push gas is delivered to the ampoule 204 and the fluid delivery line 218 via a first section 224a of a gas delivery line 224. The gas delivery line 224 is at least partially housed in the cabinet 202. The first section 224a of the gas delivery line 224 is fluidly couple to the ampoule 204 via a gas inlet port 214. In other implementations, which may be combined with other implementations described herein, the source material can be circulated through a circulation line 225 connected to the fluid delivery line 218. The circulation line 225 connects the fluid delivery line 218 and the ampoule 204. The circulation line 225 allows the source material to be circulated such that there is no trapped push gas in the fluid delivery line 218.

At operation 330, the first isolation valve 206 is closed. The first isolation valve 206 is closed such that the fixed volume 222 is filled with a fixed volume of the source material. The fixed volume 222 is between about 1 mL and about 1000 mL. In some implementations, which may be combined with other implementations described herein, the opening and closing of the first isolation valve 206 and the second isolation valve 208 is facilitated and controlled by a controller 160. The first isolation valve 206 may be closed when the calibration cylinder 210 confirms that the fixed volume 222 is filled.

At operation 340, the second isolation valve 208 is opened to allow the delivery of the source material to the evaporation system 100. When the second isolation valve 208 is opened, the fixed volume 222 becomes in fluid communication with the evaporation system 100. The source material flows through the fluid delivery line 218 to a fluid inlet port 170 of the evaporation system. The source material is delivered to a crucible 130 (shown in FIG. 1) in the evaporation system 100. As the evaporation system 100 is in a vacuum environment and the cabinet is in an atmospheric pressure environment, the pressure differential draws the source material from the fixed volume 222 to the evaporation system 100. In some implementations, which may be combined with other implementations described herein, the pressure differential applies an acceptable pressure range of between about 40 mbar and about 500 mbar (e.g., from about 40 mbar to about 100 mbar) to the source material. The fluid delivery system 200 described herein allows for an improvement in the acceptable pressure range applied to the source material. For example, the acceptable pressure range will reduce splashing of the source material in the crucible 130. Decreasing the pressure applied to the source material will decrease the splashing of the source material in the evaporation system 100. The fixed volume of the source material delivered to the evaporation system 100 allows for the prevention of underfilling and overfilling the crucible 130, as the exact volume measurement of the source material may be accounted for in subsequent operations.

In some implementations, which may be combined with other implementations described herein, in addition to the pressure differential, the push gas provides a pressure to the source material to deliver the source material to the evaporation system 100. The push gas is delivered to the fluid delivery line 218 via the first section 224a and a second section 224b of a gas delivery line 224. The first section 224a of the gas delivery line 224 is fluidly coupled to the ampoule 204 via a gas inlet port 214. The second section 224b of the gas delivery line 224 is fluidly coupled to the fluid delivery line 218 via the overflow line 235. In some implementations, which may be combined with other implementations described herein, a first pneumatic valve 236 and a second pneumatic valve 238 disposed along the gas delivery line 224 define a fixed gas volume 240 of the gas delivery line 224. The second pneumatic valve 238 is closed and the first pneumatic valve 236 is open such that the fixed gas volume 240 is filled with the push gas. The first pneumatic valve 236 is closed when the fixed gas volume 240 is filled with the push gas. The push gas in the fixed gas volume 240 may then be delivered to the overflow line 235 and the fluid delivery line 218. The fixed volume of the push gas will assist in reducing the pressure applied to the source material to decrease the splashing of the source material in the evaporation system 100.

At operation 350, the crucible 130 of the evaporation system 100 is heated to evaporate the source material to be deposited on a substrate, for example, the continuous flexible substrate 108.

In summary, some of the benefits of the present disclosure include the reduction of overfilling and underfilling a crucible in an evaporation system with a source material. In some implementations, which may be combined with other implementations described herein, a fluid delivery system for delivering a fixed volume of the source material from an ampoule to the evaporation system is provided. In one implementation, which may be combined with other implementations described herein, the fixed volume of the source material is delivered to the evaporation system by utilizing isolation valves and a calibration cylinder to fill a fixed volume of a fluid delivery line prior to delivering the source material to the crucible. The fixed volume is known and therefore, the fixed volume of the source material may be delivered repeatedly. Thus, some implementations of the present disclosure described herein reduce overfilling and underfilling the crucible as well as preventing splashing in the evaporation system upon delivery of the source material.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The method described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A fluid delivery system, comprising:
an ampoule operable to hold a source material, the ampoule including a fluid outlet port and a gas inlet port;
a fluid delivery line operable to deliver the source material to an evaporation system, comprising:
a first end fluidly coupled with the fluid outlet port;
a second end operable to be in fluid communication with the evaporation system;
a first isolation valve disposed along the fluid delivery line;
a second isolation valve disposed along the fluid delivery line; and
a calibration cylinder disposed along the fluid delivery line between the first isolation valve and the second isolation valve.

2. The fluid delivery system of claim 1, further comprising a push gas source in fluid communication with the fluid delivery line, the push gas source operable to hold a push gas.

3. The fluid delivery system of claim 2, wherein the push gas is selected from helium, nitrogen, argon, or combinations thereof.

4. The fluid delivery system of claim 3, further comprising a gas delivery line connecting the push gas source and the fluid delivery line, the gas delivery line comprising:
a first section of the gas delivery line fluidly coupled to the gas inlet port; and
a second section of the gas delivery line fluidly coupled to the fluid delivery line between the first isolation valve and the calibration cylinder.

5. The fluid delivery system of claim 4, wherein the gas delivery line further comprises:
a first pneumatic valve disposed along the gas delivery line;
a second pneumatic valve disposed downstream of the first pneumatic valve;
a metering valve disposed downstream of the second pneumatic valve; and
a pressure gauge disposed downstream of the metering valve.

6. The fluid delivery system of claim 1, the source material is selected from molten lithium, sodium, magnesium, zinc, cadmium, aluminum, gallium, indium, thallium, selenium, tin, lead, antimony, bismuth, tellurium, alkali earth metals, silver, or combinations thereof.

7. The fluid delivery system of claim 1, further comprising a circulation line fluidly coupled to the fluid delivery line between the second isolation valve and the calibration cylinder and fluidly coupled to the ampoule.

8. A deposition system, comprising:
an evaporation system having a fluid inlet port;
a fluid delivery system, comprising:
an ampoule operable to hold a source material, the ampoule including a fluid outlet port and a gas inlet port;
a fluid delivery line operable to deliver the source material to the evaporation system, comprising:
a first end fluidly coupled with the fluid outlet port;
a second end fluidly coupled to the fluid inlet port;
a first isolation valve disposed along the fluid delivery line;
a second isolation valve disposed along the fluid delivery line; and
a calibration cylinder disposed along the fluid delivery line between the first isolation valve and the second isolation valve.

9. The deposition system of claim 8, further comprising a push gas source in fluid communication with the fluid delivery line, the push gas source operable to hold a push gas.

10. The deposition system of claim 9, wherein the push gas is helium, nitrogen, argon, or combinations thereof.

11. The deposition system of claim 10, further comprising a gas delivery line connecting the push gas source and the fluid delivery line, the gas delivery line comprising:
a first section of the gas delivery line fluidly coupled to the gas inlet port; and
a second section of the gas delivery line fluidly coupled to the fluid delivery line between the first isolation valve and the calibration cylinder.

12. The deposition system of claim 11, wherein the gas delivery line further comprises:
a first pneumatic valve disposed along the gas delivery line;
a second pneumatic valve disposed downstream of the first pneumatic valve;
a metering valve disposed downstream of the second pneumatic valve; and
a pressure gauge disposed downstream of the metering valve.

13. The deposition system of claim 8, the source material is selected from molten lithium, sodium, magnesium, zinc, cadmium, aluminum, gallium, indium, thallium, selenium, tin, lead, antimony, bismuth, tellurium, alkali earth metals, silver, or combinations thereof.

14. The deposition system of claim 8, further comprising a circulation line fluidly coupled to the fluid delivery line between the second isolation valve and the calibration cylinder and fluidly coupled to the ampoule.

15. The deposition system of claim 8, wherein the evaporation system further comprises:
a deposition surface operable for depositing the source material onto a substrate provided on the deposition surface; and
a crucible positioned for depositing the source material onto the substrate.

16. A method of fluid delivery, comprising:
opening a first isolation valve disposed along a fluid delivery line and closing a second isolation valve disposed along the fluid delivery line, wherein the fluid delivery line comprises:
a first end fluidly coupled with an ampoule holding a source material;
a second end in fluid communication with a crucible;
a first isolation valve disposed along the fluid delivery line;
a second isolation valve disposed along the fluid delivery line, the first isolation valve and the second isolation valve defining a fixed volume of the fluid delivery line; and
a calibration cylinder disposed along the fluid delivery line between the first isolation valve and the second isolation valve;
delivering the source material from the ampoule to fill the fixed volume of the fluid delivery line, the source material passing through the calibration cylinder;
closing the first isolation valve when the fixed volume of the fluid delivery line is filled; and
opening the second isolation valve such that the fixed volume of the source material flows through the fluid delivery line to the crucible.

17. The method of claim 16, further comprising flowing a push gas from a push gas source to the fluid delivery line via a gas delivery line, the gas delivery line in fluid communication with the push gas source and the fluid delivery line.

18. The method of claim 17, further comprising filling a fixed gas volume of the gas delivery line with the push gas, the fixed gas volume defined by a first pneumatic valve and a second pneumatic valve downstream of the first pneumatic valve, wherein the first pneumatic valve is open and the second pneumatic valve is closed.

19. The method of claim 18, further comprising opening the second pneumatic valve when the fixed gas volume is filled with the push gas, the push gas delivered to the fluid delivery line via the gas delivery line to apply a pressure to the source material.

20. The method of claim 16, wherein the calibration cylinder disposed in the fixed volume monitors the source material and confirms when the fixed volume is filled with the source material.
